(19) United States
(12) Patent Application Publication
(10) Pub. No.: US 2008/0001575 A1
(43) Pub. Date: Jan. 3, 2008

(54) Circuit for monitoring a battery voltage

(75) Inventors: Andreas Bonin, Dresden (DE); Lutz Dathe, Dresden (DE)

Correspondence Address: MCGRATH, GEISSLER, OLDS & RICHARDSON, PLLC, P.O. BOX 1364, FAIRFAX, VA, 22038-1364, US

(73) Assignee: Atmel Germany GmbH

(21) Appl. No.: 11/808,415

(22) Filed: Jun. 8, 2007

Related U.S. Application Data
(60) Provisional application No. 60/811,800, filed on Jun. 8, 2006.

(30) Foreign Application Priority Data
Jun. 8, 2006 (DE) DE10 2006 026 666

(51) Int. Cl. G01R 31/36; H02J 7/00

(52) U.S. Cl. 320/136

(57) ABSTRACT

A method, circuit, and use for monitoring a battery voltage is provided that includes a reference voltage source having a reference voltage, a first switchable voltage divider which is connected or connectable to the battery voltage, a second switchable voltage divider which is connected to the reference voltage source, and a comparator which is connected to the first switchable voltage divider and to the second switchable voltage divider for comparison of a first divider voltage from the first switchable voltage divider to a second divider voltage from the second switchable voltage divider.

This nonprovisional application claims priority to German Patent Application No. DE 102006026666, which was filed in Germany on Jun. 8, 2007, and to U.S. Provisional Application No. 60/811,800, which was filed on Jun. 8, 2007, and which are both herein incorporated by reference.

### BACKGROUND OF THE INVENTION

1. Field of the Invention

The present invention relates to a circuit for monitoring a battery voltage, in particular for a battery-operated wireless system.

2. Description of the Background Art

Rechargeable and non-rechargeable batteries have a voltage characteristic which, for example, is a function of the charge state or the temperature of the battery. The change in the battery voltage during operation is particularly significant when the battery is almost discharged. Thus, to determine the charge state of a battery, the instantaneous battery voltage may be checked by comparing to a reference voltage. The result of this comparison may be displayed optically or acoustically, for example, and may indicate to the user that the battery should be replaced with a charged battery or recharged when the battery voltage drops below a specified target value.

A voltage indicator for displaying the exceedance of a specified value of a battery voltage is known from DE 699 22 938 T2, which corresponds to U.S. Pat. No. 6,194,868. One input terminal of a comparator is connected to the battery terminal. Another input terminal of the comparator is connected to a selector for switching the reference voltage between two values.

### SUMMARY OF THE INVENTION

It is therefore an object of the present invention to provide the simplest possible integratable circuit for monitoring a battery voltage.

Consequently, a circuit for monitoring a battery voltage of a sealed battery is provided. The circuit has a reference voltage source whose reference voltage is advantageously independent from the battery voltage. The reference voltage source also preferably has only a slight temperature dependency. The reference voltage emitted by the reference voltage source is, for example, lower than the battery voltage which is possible shortly before discharge.

The circuit also has a first switchable voltage divider which is connectable to the battery voltage, for example by attachment to the battery. It is also possible for the first switchable voltage divider for a rechargeable battery to be connected to same.

The circuit also has a second switchable voltage divider which is connected to the reference voltage source. The first voltage divider and the second voltage divider have a switchable design when at least two different voltages of a different divider ratio can be emitted by the particular voltage divider at one output by switching, for example by means of a transistor.

The circuit also has a comparator, which for comparison of a first divider voltage of the first switchable voltage divider to a second divider voltage of the second switchable voltage divider is connected to the first switchable voltage divider and to the second switchable voltage divider. The first divider voltage, by switching of the first voltage divider, and/or the second divider voltage, by switching of the second voltage divider, may preferably be modified in multiple increments.

According to an embodiment the second switchable voltage divider has a multiplexer. The multiplexer is designed for switching the second divider voltage to the comparator. For this purpose the second voltage divider has multiple divider voltage taps which may be connected to the comparator via the multiplexer. It is also possible for the first switchable voltage divider to have a multiplexer. On the other hand, in one particularly simple refinement of the invention the first switchable voltage divider has a switching transistor for modifying a voltage divider ratio. For example, the switching transistor is connected in such a way that a divider element of the voltage divider can be short-circuited by actuating the switching transistor.

In another embodiment of the invention, the first switchable voltage divider and/or the second switchable voltage divider are connected to a control logic system for control. The control logic system is, for example, a microcontroller which has a number of digital outputs for controlling the switchable voltage dividers. As an example, a digital output is provided in the form of a serial peripheral interface (SPI) connection. The logic control system is advantageously set up for a program sequence in which the battery voltage is monitored.

Preferably, the comparator is likewise connected to the logic control system for evaluating an output signal from the comparator. The comparator emits a signal which is a function of the comparison result. The logic control system is preferably designed to switch the first switchable voltage divider and the second switchable voltage divider as a function of the evaluation of the output signal from the comparator.

For example, in each case the threshold is switched by one lower increment when the battery voltage drops below the threshold. When a new, fully charged battery is used, or for another initialization, the highest threshold is selected by switching the first voltage divider and/or the second voltage divider, and the first voltage divider and/or the second voltage divider are switched again as a function of the comparison result, based on the output signal from the comparator. The battery type is advantageously determined from a characteristic of the voltage curve regarding the discharge time or charge time. For the monitoring, a threshold corresponding to the battery type is advantageously set by switching the first voltage divider and/or the second voltage divider.

To prevent oscillations, in an embodiment the comparator has a threshold value switch, whereby an input of the logic control system is connected to an output of the threshold value switch, preferably a Schmitt trigger. The Schmitt trigger ensures that a digital signal (logical 1 or logical 0) is present at the input of the logic control system.

According to another embodiment, the logic control system is designed for determining the battery voltage, in particular by successive approximation. For such a determination, the first switchable voltage divider and/or the second switchable voltage divider are switched in such a way that the instantaneous battery voltage is determined by stepwise approximation, based on the continuously checked comparison results.

In an embodiment of the invention, the first voltage divider has a number of transistors, in particular field effect transistors, as divider elements. For example, the battery voltage may be divided by three similar transistors, such as by three PMOS field effect transistors, so that, for example, the divider voltages comprising the battery voltage, two-thirds of the battery voltage, and one-third of the battery voltage may be switched by the first voltage divider.

According to an embodiment, at least one transistor which acts as a divider element is connected such that the transistor may be controlled in a double function for deactivating the first voltage divider. When PMOS field effect transistors, for example, are used as divider elements, the transistor that is connected to ground potential (negative battery potential) is controllable by the gate potential. If the gate potential is equal to the ground potential, the PMOS field effect transistor acts as a divider element On the other hand, if the gate potential is equal to a positive battery potential, the PMOS field effect transistor has a blocking effect and the first voltage divider is deactivated.

Instead of or in addition to PMOS transistors, it is also possible to connect NMOS transistors, npn bipolar transistors, and/or pnp bipolar transistors to the first voltage divider. The transistor which is controllable for deactivating the first voltage divider is connected to the logic control system for control. The logic control system is advantageously designed and set up for cyclically checking the battery voltage at variable time intervals or as a function of the battery voltage.

Different divider elements such as a resistor, a capacitor, a diode, or a transistor may be combined together in a voltage divider. However, since the reference voltage is constant and is less than the battery voltage, in one advantageous embodiment of the invention the second switchable voltage divider has a number of integrated ohmic resistors as divider elements.

Since the reference voltage functions as a power source having constant output voltage, in one advantageous embodiment of the invention the first switchable voltage divider has a coarser resolution than the second switchable voltage divider. A coarser resolution is produced by a corresponding division factor for larger voltage increments.

The first switchable voltage divider and the second switchable voltage divider are preferably designed such that the quantization increment width of the comparison voltages resulting from the two voltage dividers is less for smaller battery voltages than for larger battery voltages.

A further object of the invention is to provide a method for monitoring a battery voltage.

In the method for monitoring a battery voltage, a first voltage divider which is connected to the battery voltage is switched by a logic control system. In addition, a second voltage divider which is connected to a reference voltage is switched by the logic control system. The first voltage divider and the second voltage divider are switched by the logic control system as a function of an evaluation of an output signal from a comparator which is connected to the first switchable voltage divider and to the second switchable voltage divider for comparing a first divider voltage from the first switchable voltage divider to a second divider voltage from the second switchable voltage divider.

A further object of the invention is to provide a use. Thus, a use of a first switchable voltage divider which is connected to the battery voltage, a second switchable voltage divider which is connected to a reference voltage source, and a comparator which is connected to the first switchable voltage divider and to the second switchable voltage divider for comparing a first divider voltage from the first switchable voltage divider to a second divider voltage from the second switchable voltage divider is provided for monitoring a battery voltage.

The monitoring is preferably performed by comparing the battery voltage to a single set threshold voltage and determining the battery voltage by stepwise approximation of a threshold voltage by switching both the first switchable voltage divider and the second switchable voltage divider, based on the continuously checked comparison results of the output signal from the comparator. A surprising effect is that a monitoring function as well as a measurement function may thus be synergistically integrated.

The previously described circuit, the previously described method, and/or the previously described use are preferably employed in a battery-operated wireless network.

The reference voltage source, the first switchable voltage divider, the second switchable voltage divider, and the comparator are preferably integrated on a semiconductor chip. The semiconductor chip has, for example, an interface for a microcontroller, for example, as a logic control system. The interface and/or the microcontroller may be integrated together with the circuit on a semiconductor chip. The microcontroller may have a computation module, for example, for control.

The previously described refinement variants are particularly advantageous both singly and in combination. All refinement variants may be combined with one another. Several possible combinations are explained in the description of the exemplary embodiments in the figures. However, these illustrated possibilities of combinations of the refinement variants are not exhaustive.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a block diagram of a circuit for monitoring a battery voltage;

FIG. 2 shows a graphical illustration of a computation rule for two voltage dividers;

FIG. 3 shows a quantization characteristic; and

FIG. 4 shows a partial circuit of a battery voltage divider.

### DETAILED DESCRIPTION

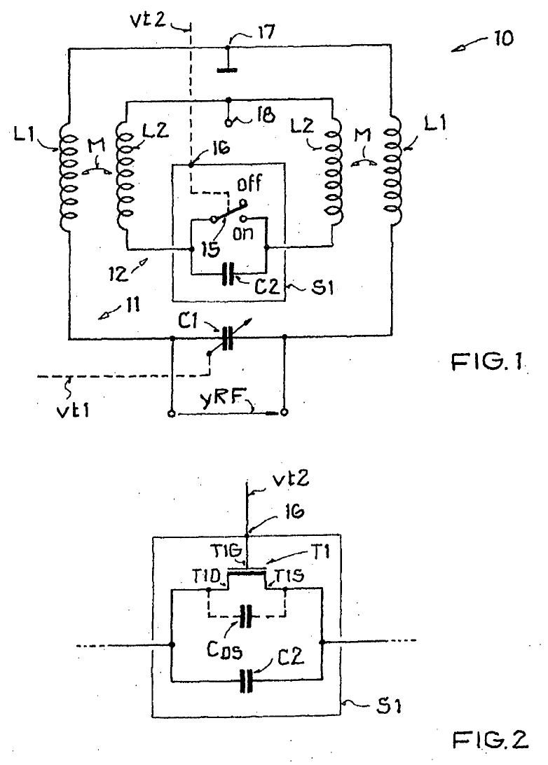

A battery monitor is a circuit for checking a battery voltage U_{B}. FIG. 1 schematically illustrates a block diagram for a battery voltage monitoring circuit 100. Various predefined comparison voltages may be set by means of a register, for example. The battery monitor 100 compares the battery voltage U_{B} to a reference voltage U_{REF} and externally delivers a result bit.

This battery voltage monitoring circuit 100 is connected to a microcontroller 200 via an interface, in the exemplary embodiment of FIG. 1 via a serial SPI interface. In addition, a battery (not illustrated in FIG. 1) having the battery voltage U_{B} is connected to the battery voltage monitoring circuit 100. From the battery voltage U_{B} the reference voltage U_{REF} is generated by means of a reference voltage source (likewise not illustrated in FIG. 1), the reference voltage being significantly less than the battery voltage U_{B}. The reference voltage U_{REF} is preferably independent of the temperature and of the battery voltage U_{B}, in the manner of a power source having constant voltage.

To the battery voltage U_{B} a first voltage divider 10 is connected, from which a number of n divider voltages may be tapped. For switching the n divider voltages, the voltage divider 10 is connected to a first analog multiplexer 11 which may be controlled by the microcontroller 200 via the serial SPI interface or a digital trigger circuit (not illustrated in FIG. 1). The output of the first analog multiplexer 11 is connected to a first input of a comparator 320 for supplying a divider voltage U_{B}×T_{UB}.

To the reference voltage U_{REF} (in this case the energy gap voltage) a second voltage divider 20 is connected, from which a number of m divider voltages may be tapped. For switching the m divider voltages, the voltage divider 20 is connected to a second analog multiplexer 22 which may be controlled by the microcontroller 200 via the serial SPI interface. The output of the second analog multiplexer 11 is connected to a second input of the comparator 320 for supplying a divider voltage U_{REF}×T_{UREF}. The resulting output voltage from the comparator 320 indicates whether the battery voltage U_{B} is above or below a comparison threshold.

The comparator 320 has an operational amplifier 120 and a Schmitt trigger 220, the output from the operational amplifier 120 being connected to the input of the Schmitt trigger 220. The digital output signal from the Schmitt trigger 220 arrives as a result bit at an input of the microcontroller 200 via a further connection, and a change in the output potential of the Schmitt trigger 220 generates, for example, an interrupt signal in the sequence of a program for the microcontroller 200. It is also possible to implement all connections via a single serial SPI interface.

The microcontroller 200 is connected via the serial SPI interface in such a way that the microcontroller, as necessary, sets the new comparison threshold by adjusting a division factor T_{REF} of the reference voltage U_{REF} and/or a division factor T_{UB} of the battery voltage U_{B}. In this manner it is possible to determine not only the drop in battery voltage U_{B} below the comparison threshold, but also the instantaneous battery voltage U_{B} by means of successive approximation. The circuit 100 is thus designed and set up to compare the battery voltage U_{B} to a threshold voltage, and, if necessary, to determine the battery voltage U_{B} by means of successive approximation. A monitoring function and a measurement function are thus synergistically integrated.

The comparison threshold is set by a combination of switchable battery voltage dividers 10, 11 and switchable reference voltage dividers 20, 22. By diverting the reference voltage U_{REF} and the battery voltage U_{B} into m or n respective divider voltages it is possible to generate m×n comparison thresholds. Thus, a large number of comparison thresholds may be easily generated.

A comparison voltage corresponding to the comparison threshold is calculated as follows:
U_{V}=U_{REF}(T_{UREF}/T_{UB})

T_{UREF} and T_{UB} are the respective division factors controlled by the microcontroller.

The various dividers for the battery voltage U_{B} and reference voltage U_{REF} are calculated such that the comparison voltages U_{V} seamlessly cover the specified voltage range without overlap. For this purpose, the reference voltage divider 20 provides fine resolution, whereas the battery voltage divider 10 provides coarse resolution. This is advantageous, since the reference voltage U_{REF} is constant, and fine resolution circuitry is therefore easily implemented.

An example of a calculation rule is explained with reference to FIG. 2. A factor F is inputted. F may be arbitrarily selected, but is greater than one and should be a simple fraction (⅔, for example). F×U_{REF} represents the lower boundary of the reference divider voltages. In this exemplary embodiment, m=8 reference divider voltages are generated which lie between >F×U_{REF} and <U_{REF}. These reference divider voltages may be easily determined by expanding factor F by 8. In this exemplary embodiment the reference divider voltages are 17/24; 18/24; 19/24; 20/24; 21/24; 22/24; 23/24 and 24/24, as illustrated in FIG. 2.

The battery voltage should generate n=3 divider voltages. The smallest is ⅓·U_{B}. The other two divider voltages are calculated to be ⅓·1/F·UB and ⅓·1/F²·U_{B}. Twenty-four comparison voltages U_{V} generated from the two divider voltage series are normalized to the reference voltage U_{REF} as a quantization characteristic, illustrated in FIG. 3. It is seen that the quantization increment width is different in the three voltage segments generated by the battery voltage divider 10. The increment width becomes smaller with increasingly lower battery voltages U_{B}. This is advantageous, since the relative measurement accuracy from segment to segment is approached, and is virtually constant.

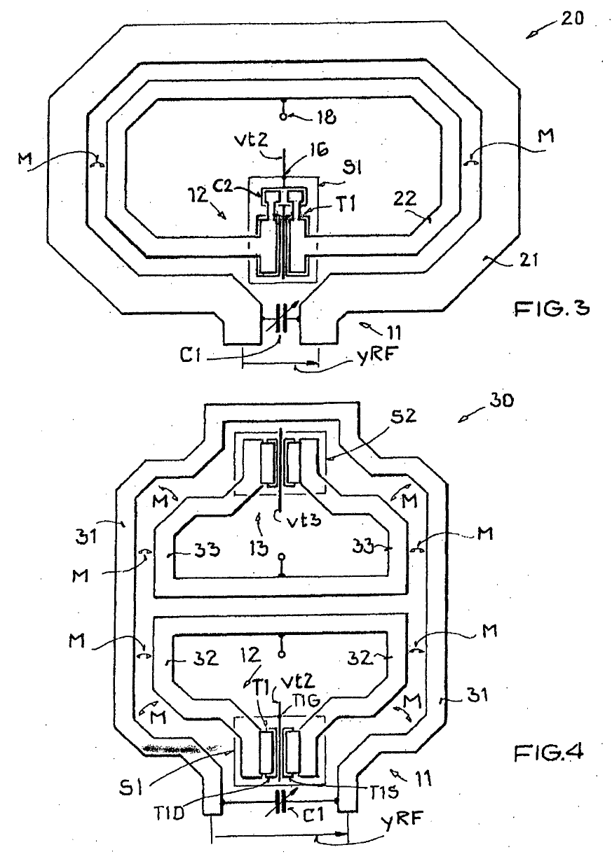

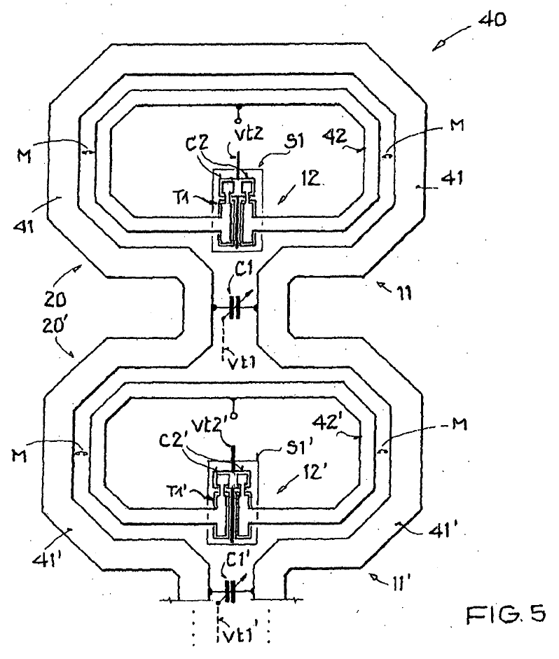

In a departure from the previously described exemplary embodiments, implementation in an integrated circuit may be achieved by designing the reference voltage divider 20 as a resistor ladder. The multiplexer 22 associated with the reference voltage divider 20 is designed as a CMOS switch having a tree structure with sixteen different reference divider voltages. The comparator 120 may likewise be designed as a simple operational amplifier. According to FIG. 4 the battery voltage divider 10 is designed as a two-stage MOS resistor ladder having three PMOS transistors M_{P1}, M_{P2}, and M_{P3}, these MOS resistor ladders being connected to the battery voltage U_{B} and to ground GND. As an ohmic resistor ladder, such a MOS resistor ladder has smaller space requirements.

The PMOS field effect transistor M_{P3} is also connected for deactivating the voltage divider 10. By application of a high potential (logical one) to the gate connection, the gate connection blocks and switches the voltage divider 10 without cross current. This has the advantage that the voltage divider 10 does not withdraw current from the battery if this is not necessary. The division factor is modified by the fact that the first transistor M_{P1} acting as a divider element is short-circuited by the switch SW. Half the battery voltage U_{B} is present (F_{UB}=½) at the output in the case of a short circuit. When the switch SW is open, a third of the battery voltage U_{B} (F_{UB}=⅓) is present at the output. The switch SW may be designed as a transistor (PMOS). The corresponding inputs T_{IN} for the switch SW and D/N for the deactivation transistor M_{P3} are, for example, directly connected to the microcontroller 200 for control.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A circuit for monitoring a battery voltage, the circuit comprising:
a reference voltage source having a reference voltage;
a first switchable voltage divider that is connected or connectable to the battery voltage;
a second switchable voltage divider that is operatively connected to the reference voltage source; and
a comparator that is operatively connected to the first switchable voltage divider and to the second switchable voltage divider for comparing a first divider voltage from the first switchable voltage divider to a second divider voltage from the second switchable voltage divider.

2. The circuit according to claim 1, wherein the second switchable voltage divider has a multiplexer for switching the second divider voltage to the comparator.

3. The circuit according to claim 1, wherein the first switchable voltage divider has a switching transistor for modifying a voltage divider ratio.

4. The circuit according to claim 1, wherein the first switchable voltage divider and/or the second switchable voltage divider are operatively connected to a logic control system for control.

5. The circuit according to claim 4, wherein the comparator is operatively connected to the logic control system for evaluating an output signal from the comparator.

6. The circuit according to claim 5, wherein the comparator has an operational amplifier and a threshold switch, in particular a Schmitt trigger, which is operatively connected to the output of the operational amplifier, one input of the logic control system being operatively connected to an output of the threshold switch for the comparator.

7. The circuit according to claim 4, wherein the logic control system is designed for determining the battery voltage by switching the first switchable voltage divider and/or the second switchable voltage divider by a stepwise approximation or by a successive approximation.

8. The circuit according to claim 1, wherein the first voltage divider has a plurality of transistors as divider elements.

9. The circuit according to claim 8, wherein at least one transistor, which acts as a divider element, is operatively connected in such a way that the transistor may be controlled for deactivating the first voltage divider.

10. The circuit according to claim 9, further comprising a controllable transistor for deactivating the first voltage divider, the controllable transistor being connected to the logic control system for control.

11. The circuit according to claim 1, wherein the second switchable voltage divider has a plurality of integrated ohmic resistors as divider elements.

12. The circuit according to claim 1, wherein the first switchable voltage divider has a coarser resolution than the second switchable voltage divider or wherein the first switchable voltage divider has a finer resolution than the second switchable voltage divider.

13. The circuit according to claim 1, wherein the first switchable voltage divider and the second switchable voltage divider are designed in such a way that a quantization increment width is less for smaller battery voltages than for larger battery voltages.

14. A method for monitoring a battery voltage, the method comprising switching, via a logic control system, a first voltage divider which is connected or connectable to a battery voltage;
switching, via the logic control system, a second voltage divider which is operatively connected to a reference voltage source; and
switching, via the logic control system, the first voltage divider and the second voltage divider as a function of an evaluation of an output signal from a comparator, which is operatively connected to the first switchable voltage divider and to the second switchable voltage divider for comparing a first divider voltage from the first switchable voltage divider to a second divider voltage from the second switchable voltage divider.

15. Use of a first switchable voltage divider, which is connected or connectable to the battery voltage of a second switchable voltage divider, which is operatively connected to the reference voltage source, and of a comparator which is operatively connected to the first switchable voltage divider and to the second switchable voltage divider for comparison of a first divider voltage from the first switchable voltage divider to a second divider voltage from the second switchable voltage divider for monitoring a battery voltage.

16. The circuit according to claim 4, further comprising a controllable transistor for deactivating the first voltage divider, the controllable transistor being connected to the logic control system for control.
